(19) United States
(12) Patent Application Publication
(10) Pub. No.: US 2014/0021444 A1
(43) Pub. Date: Jan. 23, 2014

(54) ELECTRONIC DEVICE AND MANUFACTURING METHOD THEREOF

(71) Applicants: Gyuchul Yi, Seoul (KR); Kunook Chung, Seoul (KR); Chulho Lee, Seoul (KR)

(72) Inventors: Gyuchul Yi, Seoul (KR); Kunook Chung, Seoul (KR); Chulho Lee, Seoul (KR)

(73) Assignee: SNU R&DB FOUNDATION, Seoul (KR)

(21) Appl. No.: 14/110,400

(22) PCT Filed: Apr. 16, 2012
(86) PCT No.: PCT/KR2012/002886

§ 371 Date: Oct. 7, 2013

(30) Foreign Application Priority Data
Apr. 14, 2011 (KR) 10-2011-0034856

(51) Int. Cl. H01L 29/775

(52) U.S. Cl. CPC H01L 29/775; Y10S 977/932; B82Y 99/00
USPC 257/24; 438/478; 977/932

(57) ABSTRACT

An electronic device includes a carbon layer including graphene or graphite and a thin film formed on the carbon layer. The electronic device may further include a drain electrode, a source electrode and/or a gate electrode formed on the thin film. A method of manufacturing an electronic device includes preparing a carbon layer including graphene or graphite, forming a nanostructure on the carbon layer, and forming a thin film to cover the nanostructure.

### CROSS REFERENCE TO RELATED APPLICATION

This application is the National Stage of International Application No. PCT/KR2012/002886 with an International Filing Date of Apr. 16, 2012, which claims the benefit of Korean patent application No. 10-2011-0034856 filed in the Korean Intellectual Property Office on Apr. 14, 2011, the entire contents of which are incorporated herein by reference.

### BACKGROUND

1. Technical Field

The present invention relates to an electronic device and a method of manufacturing the same.

2. Background Art

Graphene is a material having a 2-dimensional planar structure in which carbon atoms are connected to one another to form a honeycomb crystalline lattice shape. A method of experimentally obtaining graphene, namely, mechanically isolating graphene from graphite, first became known by Ander K. Geim at the University of Manchester in 2004. Research into the physical and chemical properties of graphene has continued since then. Recently, a technique of growing graphene on a 30-inch large-sized substrate using a chemical vapor deposition (CVD) process has been introduced. A layered structure having at least two grapheme layers may be referred to as graphite, namely, black lead. That is, graphene is obtained by isolating only one layer from graphite.

Graphene has excellent thermal and electrical conductivity, superior chemical/mechanical stability, and is transparent. Also, graphene has high electron mobility, low resistivity, and a large surface area, making it more commercially advantageous than carbon nanotubes. Also, graphene or graphite having a layered structure containing graphene may be easily separated from an original substrate and moved (i.e., transferred) to another substrate.

Although graphene has good physical and chemical properties as described above, there are limits to applying graphene to electronic devices. In particular, since the surface of graphene is highly chemically stable and less reactive, it is very hard to grow a structure or thin film on the graphene. Accordingly, it is difficult to integrate elements having various functional thin films on graphene and subsequently manufacturing various electronic devices, such as optical devices or memory devices.

### SUMMARY

The present invention is directed to providing an electronic device and a method of manufacturing the same, in which a thin film is formed on a carbon layer including graphene. However, aspects of the present invention should not be limited by the above description, wherein other unmentioned aspects will be clearly understood by one of ordinary skill in the art from exemplary embodiments described herein.

One aspect of the present invention provides an electronic device including: a carbon layer including graphene or graphite, and a thin film formed on the carbon layer.

Another aspect of the present invention provides an electronic device including: a carbon layer including graphene or graphite, a thin film formed on the carbon layer, and a drain electrode formed on the thin film.

Another aspect of the present invention provides an electronic device including: a carbon layer including graphene or graphite, a thin film formed on the carbon layer, and a source electrode formed on the thin film.

Another aspect of the present invention provides an electronic device including: a carbon layer including graphene or graphite, a thin film formed on the carbon layer, and a source electrode, a drain electrode, and a gate electrode formed on the thin film.

Another aspect of the present invention provides a method of manufacturing an electronic device, including the steps of: preparing a carbon layer including graphene or graphite, forming a nanostructure on the carbon layer, and forming a thin film to cover the nanostructure.

In an electronic device and a method of manufacturing the same, according to exemplary embodiments of the present invention, by forming a thin film on a carbon layer including graphene or graphite, various electronic devices, such as optical devices or memory devices, can be manufactured. In the electronic device, the carbon layer can be separated from a lower substrate and adhered to another substrate. Also, even when a metal catalyst is not used, a high-purity/high-quality electronic device containing few impurities can be provided.

### BRIEF DESCRIPTION OF DRAWINGS

FIG. 1 is a diagram of an electronic device in which a thin film is vertically grown on a carbon layer, according to an exemplary embodiment of the present invention.

FIGS. 2 through 6 are diagrams of configurations in which a thin film disposed on a carbon layer includes at least one nanostructure.

FIG. 7 is a diagram of a configuration of a multilayered film layer that uniformly covers a surface of a nanostructure constituting an electronic device according to an exemplary embodiment of the present invention.

FIGS. 8 and 9 are diagrams of an etched portion having at least one predetermined shape (including a circular shape, a triangular shape, a tetragonal shape, a pentagonal shape, a hexagonal shape, and a line shape), which is disposed on a carbon layer according to an exemplary embodiment of the present invention.

FIG. 10 is a diagram of an example in which an etched portion according to an exemplary embodiment of the present invention acts as a seed layer from which a thin film is grown.

FIG. 11 is a diagram of an example in which a nanostructure grown from an etched portion, according to an exemplary embodiment of the present invention, acts as a seed layer from which a thin film is grown.

FIG. 12 is a diagram of an example in which a thin film grown from an etched portion, according to an exemplary embodiment of the present invention, includes a plurality of thin films.

FIGS. 13 through 15 are diagrams of examples in which a mask layer including at least one opening is formed between a carbon layer and a thin film, according to an exemplary embodiment of the present invention.

FIG. 16 is a diagram of a multilayered film layer that uniformly covers a thin film constituting an electronic device, according to an exemplary embodiment of the present invention.

FIG. 17 is a diagram of an example in which a multilayered film layer, according to an exemplary embodiment of the present invention, forms a plurality of junction units with a thin film.

FIG. 18 is a diagram of an example in which a junction unit, according to an exemplary embodiment of the present invention, forms a quantum well structure.

FIG. 19 is a diagram of an example in which a junction unit, according to an exemplary embodiment of the present invention, forms a P-N junction unit.

FIGS. 20 through 24 are schematic diagrams of electronic devices according to an exemplary embodiment of the present invention.

FIGS. 25 and 26 are diagrams of an example in which an electronic device, according to an exemplary embodiment of the present invention, includes a carbon layer, a thin film, a drain electrode, a source electrode, and a gate electrode.

FIGS. 27 and 28 are diagrams of an example in which an electronic device, according to an exemplary embodiment of the present invention, includes a carbon layer, a thin film, a dielectric, a drain electrode, a source electrode, and a gate electrode.

### DETAILED DESCRIPTION

Hereinafter, exemplary embodiments of the present invention will be described in detail. However, the present invention is not limited to the exemplary embodiments disclosed below, but can be implemented in various types of embodiments. Therefore, the present exemplary embodiments are provided for complete disclosure of the present invention and serve to fully describe the scope of the present invention to those of ordinarily skill in the art. Descriptions of irrelevant components are omitted from the drawings so as to clearly describe the exemplary embodiments of the present invention. Like elements are denoted by like reference numerals in the drawings.

Throughout this specification, it will be understood that when an element is referred to as being “connected” to another element, it can be “directly connected” to the other element or “indirectly connected” to the other element with other elements therebetween. Also, it will be understood that when an element is referred to as being “on” another element, it can be directly on the other element or intervening elements may also be present. It will be further understood that when an element is referred to as “comprises” another element, the element is intended not to exclude one or more other elements, but to further include one or more other elements, unless the context clearly indicates otherwise.

Hereinafter, exemplary embodiments of the present invention will be described in detail with reference to the appended drawings.

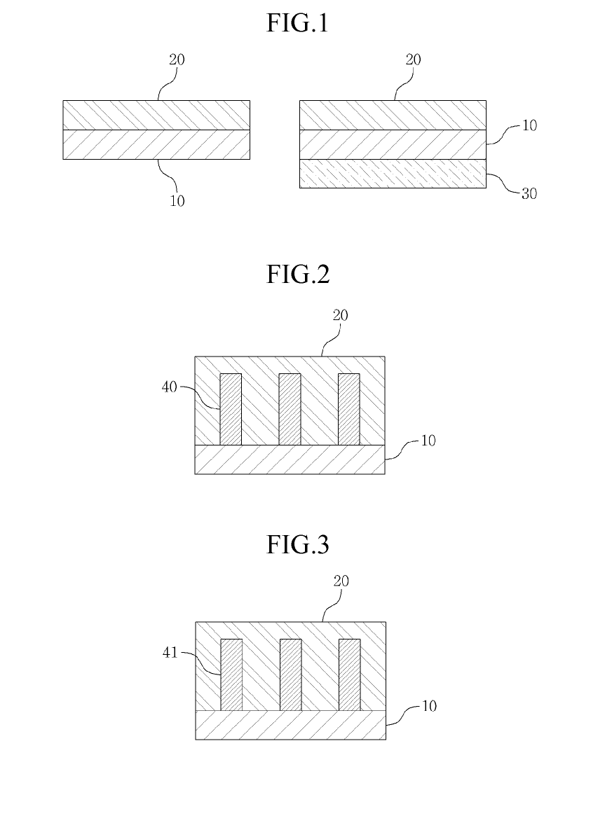

As shown in FIG. 1, an electronic device includes a carbon layer 10 and a thin film 20 formed on the carbon layer 10, and a substrate 30 may be prepared under the carbon layer 10. In the present invention, the electronic device should be interpreted as being referred to as various devices including memory devices, detection devices, diodes, transistors, emission devices, light receiving devices, solar electronic devices, or portions of the above-described devices.

The carbon layer 10 includes graphene or graphite. Graphene is a single layer in which carbon atoms are connected to one another to form a honeycomb hexagonal planar crystalline lattice structure. Graphene may have various structures, and these structures of graphene may vary according to the content of five-membered rings and/or seven-membered rings that may be included in the graphene. As described above, graphite may be interpreted as having a layered structure, having at least two layers of graphene.

The thin film 20 may be formed on the carbon layer 10. A nanostructure 40 is introduced into in the thin film 20, as described later. The thin film 20 may be formed to a thickness of, for example, about 10 nm to about 100 μm, and can be comprised of a metal or a semiconductor material.

The carbon layer 10 may be disposed on the substrate 30. However, when the carbon layer 10 has a sufficient mechanical strength, the substrate 30 is not necessary. In this case, the carbon layer 10 itself may function as a substrate without an additional substrate 30.

In addition, the carbon layer 10 may be separated from the substrate 30. Thus, the carbon layer 10 and a structure disposed thereon may be separated from the substrate 10 and transferred. This feature is very advantageous to the manufacture of electronic devices. For example, selection of the substrate 30 may be limited according to the kind of electronic device. However, since graphene may be easily separated and transferred, selection of the substrate 30 is not limited. In other words, graphene and a structure disposed thereon may be separated from an original substrate and transferred to another substrate having desired characteristics. For example, the graphene and the structure disposed thereon may be freely transferred to a flexible, modifiable polymer substrate, a transparent substrate, or a highly thermally conductive substrate. The carbon layer 10 and the substrate 30 may be separated only by mechanical force, and this process is called mechanical lift-off. The carbon layer 10 and structures disposed thereon may be separated from the substrate 30 using mechanical lift-off and transferred to another substrate, for example, a sapphire substrate, a glass substrate, a metal substrate, and/or a resin substrate. Alternatively, when the carbon layer 10 includes a plurality of graphene layers (i.e., graphite), the carbon layer 10 may be separated into at least two portions, each portion including at least one graphene layer.

The substrate 30 may be formed of any material, such as metal, glass, or resin. Materials for the substrate 30 can be, but are not limited to, for example, silicon, silicon carbide, gallium arsenide, spinel, indium prints, gallium prints, prints of aluminum, gallium nitride, indium nitride, aluminum nitride, zinc oxide, magnesium oxide, aluminum oxide, titanium oxide, sapphire, quartz, and Pyrex.

As shown in FIG. 2, the thin film 20 disposed on the carbon layer 10 may include at least one nanostructure 40.

The nanostructure 40 may act as a seed layer from which the thin film 20 is grown, and can be prepared at any arbitrary point on the carbon layer 10. The nanostructure 40 may be grown upward from the carbon layer 10. The nanostructure 40 need not be necessarily formed at right angles to the carbon layer 10, but can be formed in any arbitrary direction, using a bottom-up method with respect to a surface of the carbon layer 10, from a starting point corresponding to a contact portion between the nanostructure 40 and the carbon layer 10. Of course, the nanostructure 40 may be formed to vertically extend from the surface of the carbon layer 10.

The nanostructure 40 formed using a bottom-up method may be grown into a good crystalline structure having a very low dislocation density, despite a difference in material constant (lattice constant or coefficient of thermal expansion) between the nanostructure 40 and the carbon layer 10. Thus, the nanostructure 40 formed using a bottom-up method has higher crystallinity and better electrical and optical properties than a structure manufactured using a top-down method which is based on a thin film deposition process and an etching process. Accordingly, it is possible to manufacture an electronic device having excellent electrical and optical properties.

The nanostructure 40 is a micro-scale or nano-scale structure, and the size or shape of the nanostructure 40 is not specifically limited. For instance, a diameter (including thickness) of the nanostructure 40 may range from about 1 nm to about 500 nm, and a height of the nanostructure 40 may range from about 10 nm to about 100 μm. Also, a ratio of the length of the nanostructure 40 to the diameter (including thickness) of the nanostructure 40 may range from 1 to 1000. In the present invention, the term “nanostructure” is not necessarily limited to nano-sized structures, and should be interpreted as including any structure having a size larger or smaller than a nano-size, particularly when the structure has peculiar characteristics on a nanoscale, and has such a size and function as to form fine electronic devices.

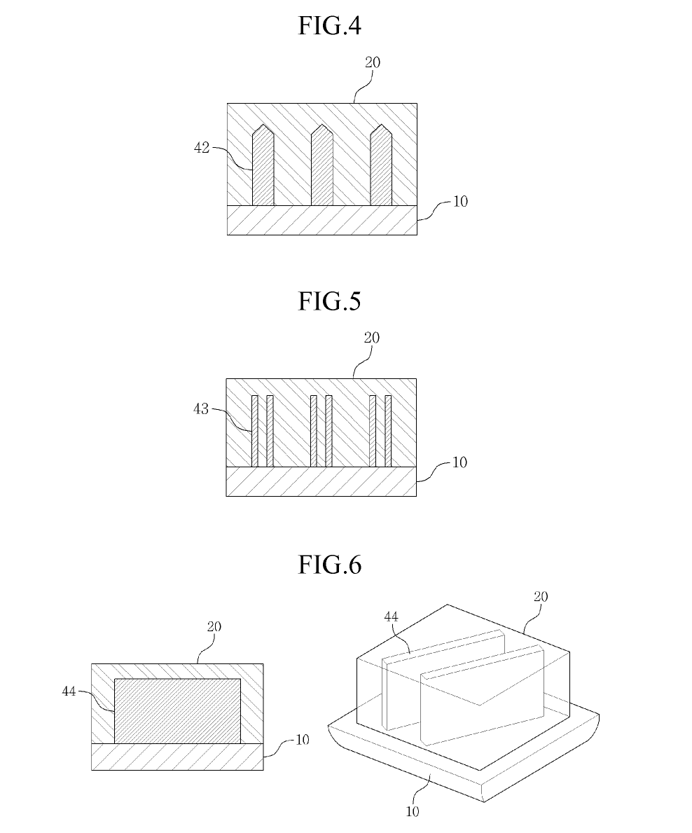

As shown in FIGS. 3 through 6, the nanostructure 40 may be, for example, a nanorod 41 (refer to FIG. 3), a nano-needle 42 (refer to FIG. 4), a nanotube 43 (refer to FIG. 5), a nano-wall 44 (refer to FIG. 6), or any combination thereof. However, the shape of the nanostructure 40 is not limited to the above-described examples.

A material of the nanostructure 40 may be a metal or a semiconductor, but is not specifically limited thereto. The material of the nanostructure 40 may be, for example, zinc oxide, zinc magnesium oxide, zinc cadmium oxide, zinc magnesium cadmium oxide, zinc beryllium oxide, zinc magnesium beryllium oxide, zinc manganese oxide, zinc magnesium manganese oxide, gallium nitride, aluminum nitride, gallium aluminum nitride, or indium gallium nitride.

The thin film 20 is formed to cover (coat) the nanostructure 40. That is, the nanostructure 40 is introduced into the thin film 20 and serves as a seed layer for forming the thin film 20. Although it is very hard to stack a thin film on graphene or graphite, by forming the nanostructure 40 on graphene or graphite, and subsequently forming the thin film 20 using the nanostructure 40 as the seed layer, it becomes easy to manufacture an electronic device.

The thin film 20 may be formed of a metal or a semiconductor material. For example, a material of the thin film 20 may be a nitride, such as gallium nitride, or an oxide, such as zinc oxide, but is not specifically limited thereto. Also, the thin film 20 may be formed of a semiconductor material, such as gallium nitride, aluminum nitride, gallium aluminum nitride, or indium gallium nitride, but is not specifically limited thereto. The thin film 20 may be formed of a material having a crystalline structure and lattice constant similar to those of the nanostructure 40, so that the thin film 20 can be compatible with the nanostructure 40.

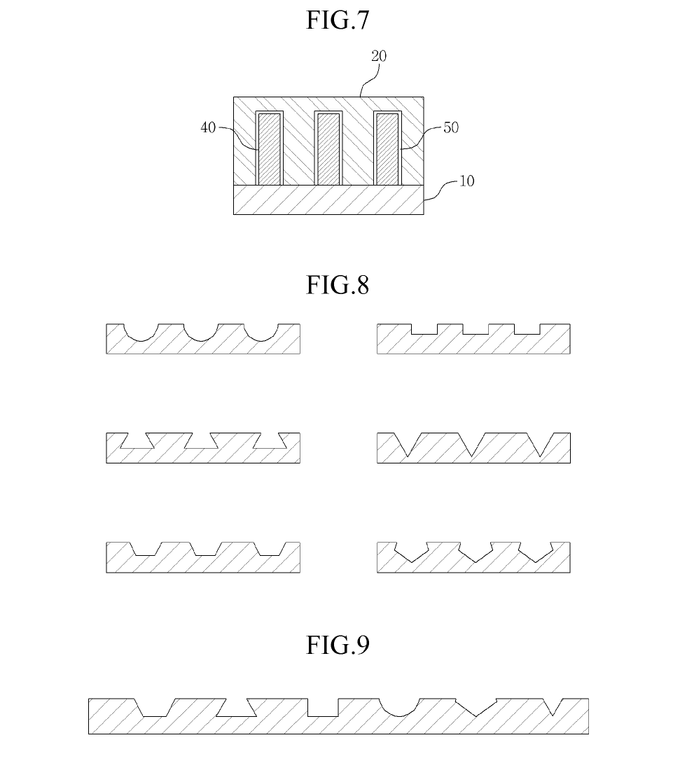

As shown in FIG. 7, the nanostructure 40 constituting the electronic device may further include a multilayered film layer 50 covering a surface of the nanostructure 40. The multilayered film layer 50 may be a functional layer, for embodying a function of the electronic device, or an insulating layer. The multilayered film layer 50 may have a thickness of about 0.1 nm to about 100 μm.

Meanwhile, a damage serving as a seed layer for growing the nanostructure 40 may be formed on the carbon layer 10. The formation of the damage will be described later. The damage may be an etched portion, and the shape of the damage is not specifically limited. However, as shown in FIG. 8, the damage may have, for example, a circular shape, a triangular shape, a tetragonal shape, a pentagonal shape, a hexagonal shape, and a line shape.

The damage may be formed to have a plurality of etched portions, and a distance between the respective etched portions may be, for example, about 1 nm to about 10 μm. The plurality of etched portions may have different shapes.

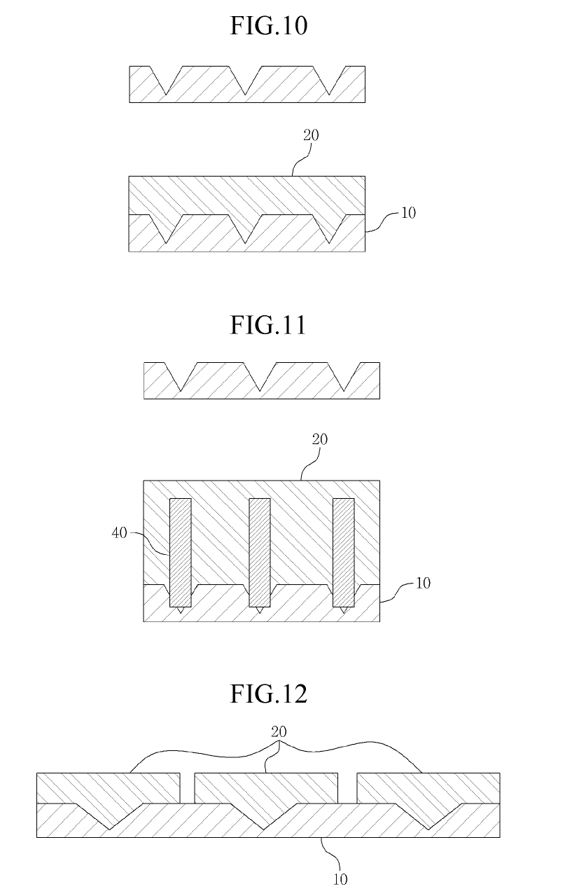

As shown in FIG. 10, a damage may directly act as a seed layer for growing the thin film 20. As shown in FIG. 11, a nanostructure 40 grown from a damage may act as a seed layer for growing the thin film 20.

In addition, as shown in FIG. 12, a thin film 20 grown from a damage may include a plurality of thin films spaced apart from one another.

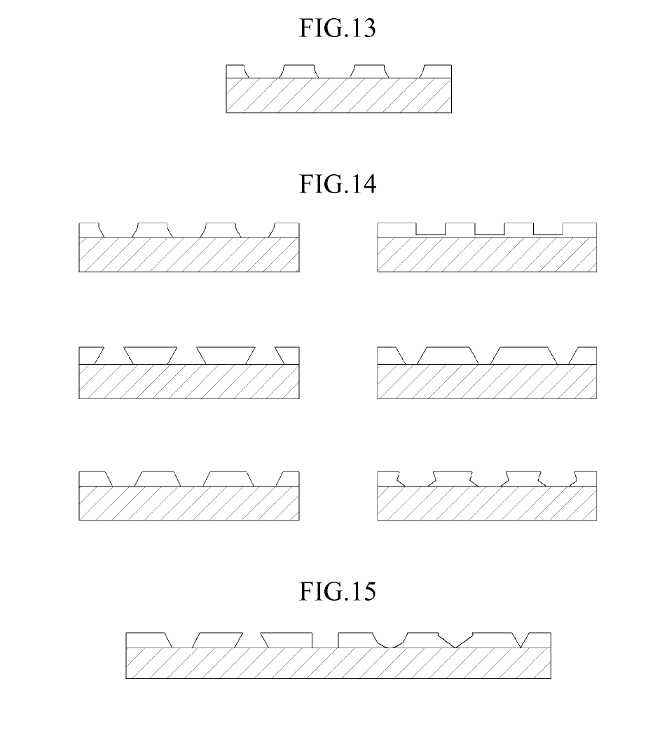

Furthermore, as shown in FIGS. 13 through 15, an electronic device may further include a mask layer formed between the carbon layer 10 and the thin film 20 and having at least one opening. FIGS. 13 through 15 illustrate only a carbon layer (as striped) and a mask layer, and a nanostructure 40 may be grown in an upward direction through openings formed in the mask layer. The openings formed in the mask layer may have an arbitrary shape, for example, a circular shape, a triangular shape, a tetragonal shape, a pentagonal shape, a hexagonal shape, and a line shape. A plurality of openings may be formed in the mask layer, and a distance between the openings may be, for example, about 1 nm to about 10 μm.

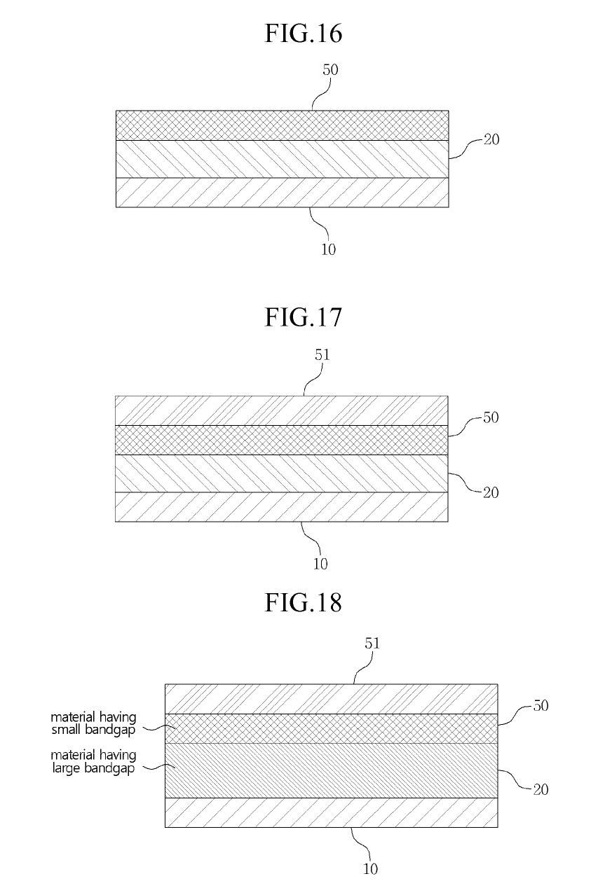

As shown in FIG. 16, a multilayered film layer 50 may be formed on the thin film 20. The multilayered film layer 50 may uniformly coat the thin film 20. Although the thickness of the multilayered film layer 50 is not specifically limited, the thickness of the multilayered film layer 50 may be, for example, about 0.1 nm to about 1000 nm.

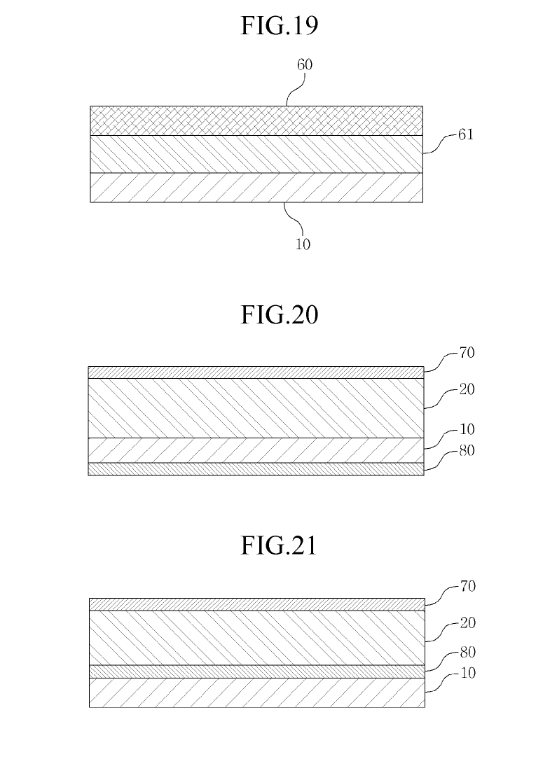

As shown in FIG. 17, the multilayered film layer 50 may form a plurality of junction units along with the thin film 20. The junction units between the multilayered film layer 50 and the thin film 20 may have a quantum well structure as shown in FIG. 18. In this case, the multilayered film layer 50 is formed of a material having a small bandgap, while the thin film 20 is formed of a material having a large bandgap. As shown in FIG. 19, the junction units between the multilayered film layer 50 and the thin film 20 may form a P-N junction unit including a p-type material 60 and an n-type material 61. Since structures, functions, materials, and forming methods of the quantum well structure and the P-N junction unit are well known, a detailed description thereof is omitted.

A configuration of an electronic device according to an exemplary embodiment of the present invention has been described thus far. Hereinafter, a method of manufacturing an electronic device will be described with reference to FIGS. 1 through 19.

To begin, a substrate 30 on which a carbon layer 10 including graphene or graphite is prepared, and a mask layer is coated on the carbon layer 10 (refer to FIGS. 1 and 13). A method of forming the carbon layer 10 on the substrate 30 may be a chemical vapor deposition (CVD) process, but is not limited thereto. For example, graphene may be physically or chemically isolated from graphite and used. Alternatively, in addition to typical CVD processes, a rapid thermal CVD (RTCVD) process, a plasma-enhanced CVD (PECVD) process, an inductively coupled plasma (ICP) CVD process, or a metal-organic chemical CVD (MOCVD) process may be used as the CVD process.

Although the present embodiment describes the carbon layer 10 as disposed on the substrate 30, the carbon layer 10 itself may be used as the substrate without the substrate 30.

Next, the mask layer may be patterned to form a plurality of openings (refer to FIGS. 13 through 15). A method of patterning the mask layer is conventionally well known in semiconductor manufacturing processes. For example, an e-beam lithography process, a photolithography process, a laser interference lithography process, or a nano-imprint process may be used. Also, a pattering method using a template, such as anodic aluminum oxide (AAO) or a block copolymer, may be used.

Thereafter, a damage (not shown) is generated on a surface of the carbon layer 10 through the openings formed in the mask layer (refer to FIGS. 8 and 9). A method for generating the damage may use gas plasma, as shown in FIG. 19, or may use ion beams, e-beams, proton beams, or neutron beams, but these methods are not limited thereto. Gases used for the gas plasma method may be oxygen (O₂), nitrogen (N₂), chlorine (Cl₂), hydrogen (H₂), argon (Ar), tetrafluoromethane (CF₄), sulfur hexafluoride (SF₆), boron trichloride (BCl₃), or ozone (O₃), but are not limited thereto.

Next, after growing a nanostructure 40 from the damage, the mask layer is removed (refer to FIGS. 2 and 4). That is, the damage becomes a seed layer for growing the nanostructure 40.

As a method of growing the nanostructure 40 on the carbon layer 10, a CVD process, including a metal-organic chemical CVD (MOCVD) process, a physical growth process, such as a sputtering process, a thermal or e-beam evaporation process, a pulse laser deposition (PLD) process, and a vapor-phase transport process, using a metal catalyst, such as gold, may be used. When a catalyst-free MOCVD process is used, contamination caused by the catalyst may be circumvented, and a nanostructure having excellent electrical and optical properties can be prepared.

As described, by artificially applying damage to a surface of the carbon layer 10 including graphene or graphite, nucleation and growth occur at the damage serving as a starting point. Accordingly, it is possible to generate the nanostructure 40 on the graphene and also becomes easy to control the position and density of the nanostructure 40.

Meanwhile, although the position and density of the nanostructure 40 have been controlled thus far by performing a patterning process and generating a damage, this specific method need not necessarily be performed. For example, it is possible to form the damage on the carbon layer 10 at random by directly performing a gas plasma etching process on the carbon layer 10 without using the mask layer. Also, it is possible to inject ion beams to the carbon layer 10 without using the mask layer. In this case, by controlling the injection position of the ion beams, the position and density of the nanostructure 40 may be controlled without using the mask layer.

Furthermore, it is not necessary to generate a damage on the carbon layer 10 and grow the nanostructure 40 from the damage serving as a starting point. For example, it is possible to grow the nanostructure 40 directly on the carbon layer 10 by appropriately selecting process conditions, such as temperature and pressure.

Next, a thin film 20 is formed to completely coat the nanostructure 40 (refer to FIG. 2). A method of forming the thin film 20 may be, for example, a CVD process. Since a method of forming a thin film is conventionally well known, a detailed description thereof is omitted.

Hereinafter, an electronic device according to another exemplary embodiment of the present invention will be described with reference to FIGS. 20 through 28. In the present embodiment, a source electrode, a drain electrode, and a gate electrode are formed on or under a thin film 20. Since a method of forming the thin film 20 on a carbon layer 10 is the same as in the previous embodiment, a repeated description thereof is omitted. Also, since a method of forming a source electrode is conventionally well known, a method of manufacturing an electronic device will not be additionally described in the present embodiment.

In addition, although the terms “source electrode” and “drain electrode” are used for brevity in the present embodiment, the source and drain electrodes are not necessarily electrodes for transistors. That is, the terms “source electrode” and “drain electrode” may be used to simply discriminate between names of electrodes. In this case, for example, the source electrode may be referred to as a first electrode, while the drain electrode may be referred to as a second electrode. Accordingly, in the present embodiment, an electronic device should be interpreted as being widely applicable to an emission device, a light receiving device, a detection device, a memory device, a transistor, and a diode.

As shown in FIGS. 20 through 23, an electronic device includes a carbon layer 10, including graphene or graphite, a thin film 20, a drain electrode 70, and a source electrode 80.

As shown in FIG. 20, an electronic device may include a source electrode 80, a carbon layer 10 formed on the source electrode 80, a thin film 20 formed on the carbon layer 10, and a drain electrode 70 formed on the thin film 20.

In addition, as shown in FIG. 21, an electronic device may include a carbon layer 10, a source electrode 80 formed on the carbon layer 10, a thin film 20 formed on the source electrode 80, and a drain electrode 70 formed on the thin film 20.

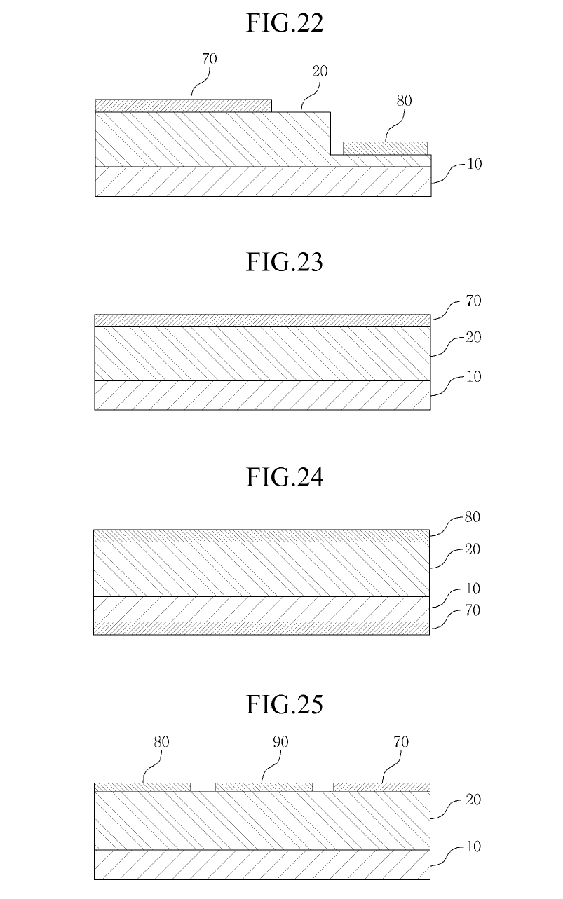

Furthermore, as shown in FIG. 22, an electronic device may include a carbon layer 10 having an end portion, a thin film 20 formed on the carbon layer 10, a drain electrode 70 formed on the thin film 20, and a source electrode 80 spaced apart from the drain electrode 70 and formed on the end portion of the thin film 20.

As described above, the source electrode 80 may be disposed on or under the carbon layer 10 or on the thin film 20. However, the carbon layer 10 itself may be used as the source electrode 80 (refer to FIG. 23). Also, the carbon layer 10 may be patterned so that one source electrode 80 can be formed in one electronic device. In this case, since source electrodes 80 are electrically insulated from one another, a voltage applied to each of electronic devices may be controlled.

As shown in FIG. 24, an electronic device may include a carbon layer 10, including graphene or graphite, a thin film 20, a drain electrode 70, and a source electrode 80. Here, the source electrode 80 may be disposed on the thin film 20, and the drain electrode 70 may be disposed on or under the carbon layer 10. Also, the carbon layer 10 itself may be used as the source electrode 80.

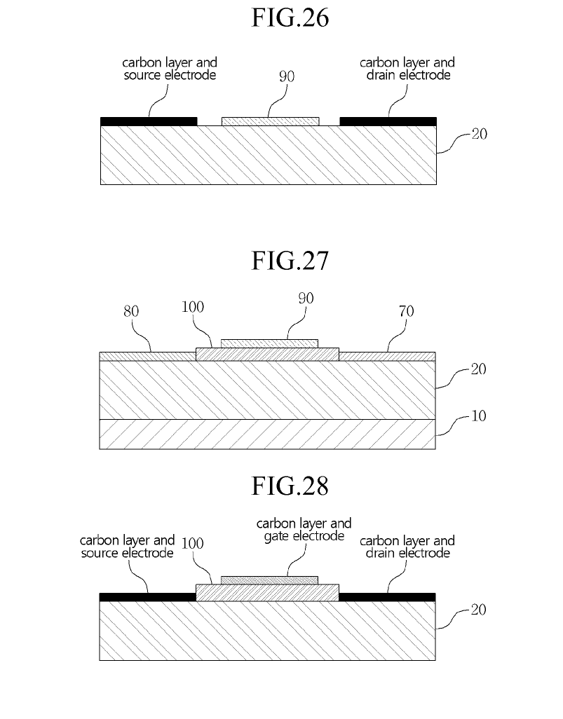

As shown in FIGS. 25 through 26, an electronic device may include a carbon layer 10, including graphene or graphite, a thin film 20, a drain electrode 70, a source electrode 80, and a gate electrode 90. Each of the electrodes (i.e., the drain electrode 70, the source electrode 80, and the gate electrode 90) may be disposed on the thin film 20, and the carbon layer 10 may be patterned and used as the drain electrode 70, the source electrode 80, or the gate electrode 90.

As shown in FIGS. 27 and 28, an electronic device may include a carbon layer 10, including graphene or graphite, a thin film 20, a dielectric 100, a drain electrode 70, a source electrode 80, and a gate electrode 90. The source electrode 80 and the drain electrode 70 may be disposed on the thin film 20, and the carbon layer 10 may be patterned and used as the drain electrode 70, or the source electrode 80 of the electronic device. The dielectric 100 may be disposed on the thin film 20, and the gate electrode 90 is disposed on the dielectric 100.

While this invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in exemplary sense only and not for purposes of limitation. For example, each component referred to as a single type may be divided, and components referred to as being divided may be combined as a single type.

Therefore, the scope of the invention is defined by the appended claims, and the meaning and scope of the claims and any changes or variations derived from the equivalent concept will be construed as being included in the present invention.

1. An electronic device comprising:
a carbon layer including graphene or graphite; and
a thin film formed on the carbon layer.

2. The device of claim 1, further comprising a nanostructure formed on the carbon layer, wherein the thin film covers the nanostructure.

3. The device of claim 2, wherein the nanostructure vertically extends from a surface of the carbon layer.

4. The device of claim 2, wherein the nanostructure is one selected from the group consisting of a nanorod, a nano-needle, a nanotube, and a nano-wall.

5. The device of claim 2, wherein the nanostructure is a seed layer from which the thin film is grown.

6. The device of claim 2, further comprising a multilayered film layer formed on a surface of the nanostructure.

7. The device of claim 1, further comprising a substrate formed under the carbon layer.

8. The device of claim 7, wherein the substrate and the carbon layer are capable of being separated from each other.

9. The device of claim 2, wherein a damage serving as a seed layer from which the nanostructure is grown, is formed on the carbon layer.

10. The device of claim 9, wherein a shape of the damage has at least one of a circular shape, a triangular shape, a tetragonal shape, a pentagonal shape, a hexagonal shape, and a line shape.

11. The device of claim 9, wherein the damage is an etched portion.

12. The device of claim 1, further comprising a mask layer interposed between the carbon layer and the thin film and having at least one opening.

13. The device of claim 1, further comprising a multilayered film layer formed on the thin film.

14. The device of claim 13, wherein the multilayered film layer forms a plurality of junction units along with the thin film.

15. The device of claim 14, wherein each of the junction units includes a quantum well structure.

16. The device of claim 14, wherein each of the junction units is a P-N junction unit.

17. The device of claim 1, further comprising:
at least one of a drain electrode, a source electrode, and a gate electrode formed on the thin film.

18. The device of claim 17, further comprising a source electrode,
wherein the source electrode is formed under the carbon layer or between the carbon layer and the thin film or on the thin film; and
the drain electrode is formed under the carbon layer or between the carbon layer and the thin film.

19. (canceled)

20. (canceled)

21. (canceled)

22. The device of claim 17, wherein the gate electrode is formed on the thin film, and the device further comprises a dielectric formed between the thin film and the gate electrode.

23. A method of manufacturing an electronic device, comprising:
preparing a carbon layer including graphene or graphite;
forming a nanostructure on the carbon layer; and
forming a thin film to cover the nanostructure.

24. The method of claim 23, wherein the preparation of the carbon layer comprises preparing the carbon layer including the graphene or graphite on a substrate.

25. The method of claim 23, wherein the formation of the nanostructure comprises:
generating a damage on the carbon layer; and
growing the nanostructure using the damage as a seed layer.

26. The method of claim 25, wherein the generation of the damage comprises:
forming a mask layer on the carbon layer;
patterning the mask layer and forming a plurality of openings on the mask layer; and
generating a damage on the carbon layer through the openings.

27. The method of claim 26, wherein the patterning of the mask layer and the forming of the plurality of openings uses at least one of an electronic beam (e-beam) lithography process, a photolithography process, a laser interference lithography process, a nano-imprint process, and a template process.

28. The method of claim 25, wherein the generation of the damage uses at least one method of gas plasma, ion beams, e-beams, proton beams, and neutron beams.

29. The method of claim 23, wherein the nanostructure is selected from the group consisting of a nanorod, a nano-needle, a nanotube, and a nano-wall.
